(19) United States
(12) Patent Application Publication
(10) Pub. No.: US 2023/0345841 A1
(43) Pub. Date: Oct. 26, 2023

(54) MAGNETORESISTIVE RANDOM-ACCESS MEMORY STRUCTURE

(71) Applicant: INTERNATIONAL BUSINESS MACHINES CORPORATION, ARMONK, NY (US)

(72) Inventors: Hsueh-Chung Chen, Cohoes, NY (US); Koichi Motoyama, Clifton Park, NY (US); CHANRO PARK, CLIFTON PARK, NY (US); Chih-Chao Yang, Glenmont, NY (US)

(21) Appl. No.: 17/660,027

(22) Filed: Apr. 21, 2022

(51) Int. Cl. H01L 43/08; H01L 27/22; H01L 43/02; H01L 43/12; H01L 23/48

(52) U.S. Cl. CPC H01L 43/08; H01L 27/226; H01L 43/02; H01L 43/12; H01L 23/481

(57) ABSTRACT

Embodiments of present invention provide a method of forming electrode to a magnetic-tunnel junction device. The method includes providing a supporting structure; depositing a layer of conductive material on top of the supporting structure; performing a first etching of the layer of conductive material to form a connection layer; and performing a second etching of a remaining portion of the layer of conductive material to form a micro-stud, the micro-stud being directly above the connection layer. In one embodiment the supporting structure includes a via opening and the conductive material fills the via opening to form a via.

### BACKGROUND

The present application relates to manufacturing of semiconductor integrated circuits. More particularly, it relates to a magnetoresistive random-access memory structure and method of manufacturing the same.

Magnetoresistive random-access memory (MRAM) is a type of non-volatile random-access memory (RAM) that stores data in magnetic domains. Unlike conventional RAM chip technologies, data in MRAM is not stored as electric charge or current flows, but by magnetic storage elements. The elements are formed from two ferromagnetic plates, each of which can hold a magnetization, separated by a thin insulating layer. One of the two plates is a permanent magnet set to a particular polarity while magnetization of the other plate can be changed to match that of an external field, such as that from a bit line, to store a logic “1” or “0”. The MRAM is usually powered by an access transistor whose source/drain contact is connected to the MRAM through an electrode.

An MRAM may situate within a back-end-of-line (BEOL) stack such as, for example, between two metal layers, e.g., a top metal layer and a bottom metal layer relative to the MRAM. Access to an MRAM may be made through a stack of metallic elements such as vias underneath the bottom metal with a CMOS device. The via or vias may be formed, for example in the currently existing process, through three separate single damascene and metallization processes. Using currently existing process, the bottom connecting via, known as micro-stud, formed to connect to the MRAM have often been found of containing voids. The voids unfortunately cause open circuit resulting failure or malfunction of the MRAM that the micro-stud connects to.

### SUMMARY

Embodiments of present invention provide a method of forming an electrode to a magnetoresistive random-access memory (MRAM). The method includes providing a supporting structure; depositing a layer of conductive material on top of the supporting structure; performing a first etching of the layer of conductive material to form a connection layer; and performing a second etching of a remaining portion of the layer of conductive material to form a micro-stud, the micro-stud being directly above the connection layer.

In one embodiment, providing the supporting structure includes providing a source/drain contact of an access transistor; covering the source/drain contact with a first dielectric layer; and creating a via opening in the first dielectric layer to form the supporting structure, with the via opening exposing the source/drain contact of the access transistor.

Embodiments of present invention further provide a magnetoresistive random-access memory (MRAM) structure. The MRAM structure includes a magnetic-tunnel junction (MTJ) device having a first and a second contact areas; a micro-stud in contact with the first contact area of the MTJ device; and a bit line in contact with the second contact area of the MTJ device, wherein the micro-stud is directly above a connection layer; the connection layer is directly above a via; and the via directly contacts a source/drain region of an access transistor, and wherein the micro-stud, the connection layer, and the via together form a single unit.

In one embodiment, the unitary electrode for the MRAM is made of ruthenium (Ru), cobalt (Co), aluminum (Al), and/or tungsten (W).

### BRIEF DESCRIPTION OF THE DRAWINGS

The present invention will be understood and appreciated more fully from the following detailed description of embodiments of present invention, taken in conjunction with accompanying drawings of which:

FIGS. 1-10 are demonstrative illustrations of cross-sectional views of a device structure in a process of forming an electrode to a magnetoresistive random-access memory (MRAM) according to embodiments of present invention; and

FIG. 11 is a demonstrative illustration of a flow-chart of a method of forming an electrode to a MRAM according to embodiments of present invention.

It will be appreciated that for simplicity and clarity purpose, elements shown in the drawings have not necessarily been drawn to scale. Further, and if applicable, in various functional block diagrams, two connected devices and/or elements may not necessarily be illustrated as being connected. In some other instances, grouping of certain elements in a functional block diagram may be solely for the purpose of description and may not necessarily imply that they are in a single physical entity or they are embodied in a single physical entity.

### DETAILED DESCRIPTION

In the below detailed description and the accompanying drawings, it is to be understood that various layers, structures, and regions shown in the drawings are both demonstrative and schematic illustrations thereof that are not drawn to scale. In addition, for the ease of explanation, one or more layers, structures, and regions of a type commonly used to form semiconductor devices or structures may not be explicitly shown in a given illustration or drawing. This does not imply that any layers, structures, and regions not explicitly shown are omitted from the actual semiconductor structures. Furthermore, it is to be understood that the embodiments discussed herein are not limited to the particular materials, features, and processing steps shown and described herein. In particular, with respect to semiconductor processing steps, it is to be emphasized that the descriptions provided herein are not intended to encompass all of the processing steps that may be required to form a functional semiconductor integrated circuit device. Rather, certain processing steps that are commonly used in forming semiconductor devices, such as, for example, wet cleaning and annealing steps, are purposefully not described herein for economy of description.

It is to be understood that the terms “about” or “substantially” as used herein with regard to thicknesses, widths, percentages, ranges, etc., are meant to denote being close or approximate to, but not exactly. For example, the term “about” or “substantially” as used herein implies that a small margin of error may be present such as, by way of example only, 1% or less than the stated amount. Likewise, the terms “on”, “over”, or “on top of” that are used herein to describe a positional relationship between two layers or structures are intended to be broadly construed and should not be interpreted as precluding the presence of one or more intervening layers or structures.

Moreover, the same or similar reference numbers are used throughout the drawings to denote the same or similar features, elements, or structures, and thus, a detailed explanation of the same or similar features, elements, or structures may not be repeated for each of the drawings for economy of description.

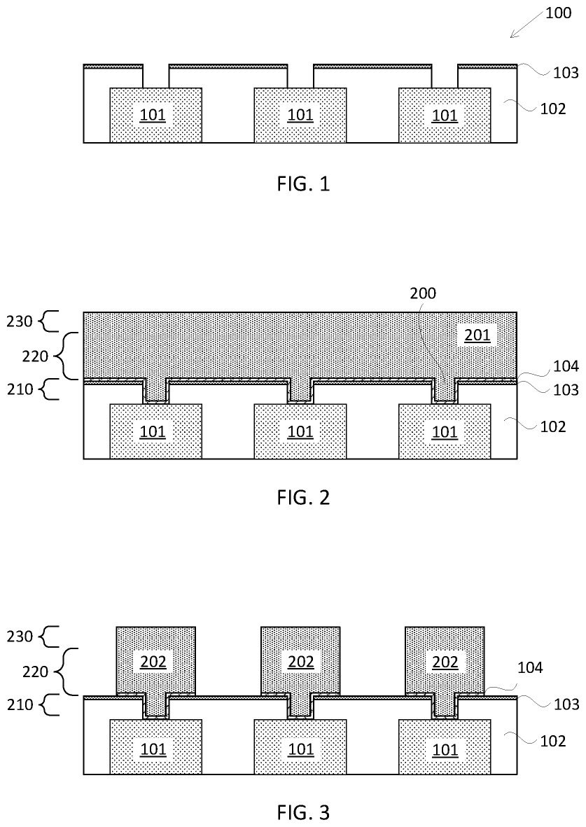

FIGS. 1-9 are demonstrative illustrations of cross-sectional views of a device structure in a process of forming an electrode to a magnetoresistive random-access memory (MRAM) according to embodiments of present invention. More specifically, referring to FIG. 1 which demonstratively illustrates a supporting structure 100. The supporting structure 100 may include one or more source/drain contacts 101 of one or more respective access transistors made for one or more MRAMs. The source/drain contacts 101 may be covered by a first dielectric layer 102 which may be a silicon-nitride (SiN). The first dielectric layer 102 may in-turn be covered by a liner 103 which serves as an etch stop layer. The liner 103 may be made from a layer of, for example, NBLok, silicon-carbide (SiC), silicon-carbon-nitride (SiCN), and/or silicon-nitride (SiN). One or more via openings are created in the first dielectric layer 102 to expose at least one of the source/drain contacts 101, to which an electrode to a magnetic tunnel junction (MTJ) device of the MRAM is to be made.

FIG. 2 is a demonstrative illustration of cross-sectional view of a device structure in a process of forming an electrode to a MRAM, following the step illustrated in FIG. 1, according to one embodiment of present invention. More specifically, after forming an optional liner 104 such as, for example, a tantalum-nitride (TaN) liner on top of the supporting structure 100 to line the via openings, a layer 201 of conductive material may be deposited on top of the first dielectric layer 102 above the liner 104. The layer 201 of conductive material may fill the via openings to form vias, such as a via 200, above at least one of the source/drain contacts 101. The layer 201 of conductive material may be deposited to have a thickness. This thickness may be designed and/or made to be equal to or larger than a thickness 220 of a connection layer (to be formed later) plus a thickness 230 of a micro-stud layer (to be formed later). Including a thickness 210 of the via 200 formed inside the via opening, the layer 201 of conductive material may have a total thickness ranging from about 1 nm to about 500 nm. The layer 201 may be made of conductive material including, but not limited to, ruthenium (Ru), cobalt (Co), aluminum (Al), and tungsten (W).

FIG. 3 is a demonstrative illustration of cross-sectional view of a device structure in a process of forming an electrode to a MRAM, following the step illustrated in FIG. 2, according to one embodiment of present invention. More specifically, embodiments of present invention provide performing a first etching of the layer 201 to form a modified layer 202 of conductive material. In other words, the modified layer 202 is a remaining portion of the layer 201 after the first etching and a lower portion thereof, up to the thickness 220, may be formed as a connection layer 203, as being described below in more details with reference to FIG. 6.

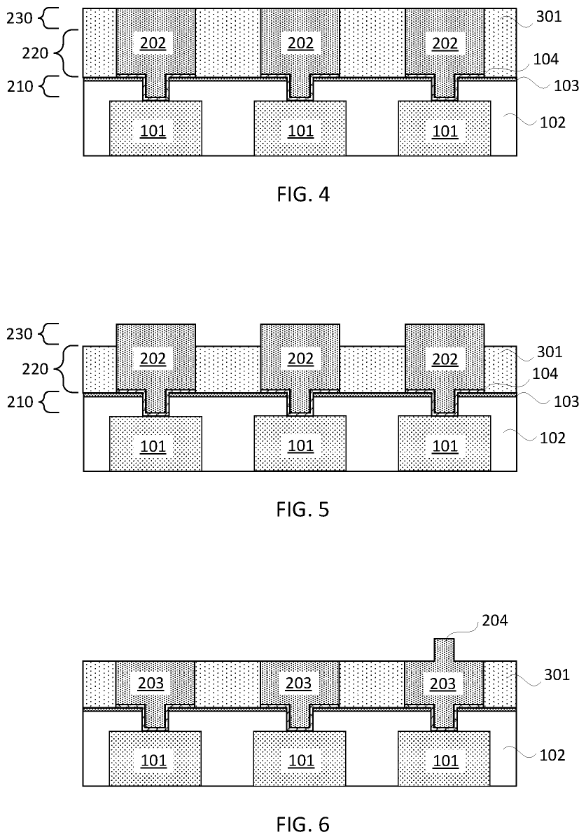

FIG. 4 is a demonstrative illustration of cross-sectional view of a device structure in a process of forming an electrode to a MRAM, following the step illustrated in FIG. 3, according to one embodiment of present invention. More specifically, embodiments of present invention provide depositing a layer 301 of oxide or low-k dielectric material on top of the modified layer 202. The deposition of the layer 301 is followed by a chemical-mechanic-polishing (CMP) process to planarize a top surface of the layer 301 and reveal a top surface of the modified layer 202.

FIG. 5 is a demonstrative illustration of cross-sectional view of a device structure in a process of forming an electrode to a MRAM, following the step illustrated in FIG. 4, according to one embodiment of present invention. More specifically, embodiments of present invention provide etching back the oxide or low-k dielectric material of the layer 301 in between the modified layer 202 to reveal a top portion thereof. More particularly, the layer 301 may be recessed to a depth to reveal a portion of the modified layer 202 that corresponds to the thickness 230 of a micro-stud layer (to be formed later). In the meantime, the remaining portion of the modified layer 202 that are covered by the layer 301 corresponds to the connection layer 203, as illustrated in FIG. 6.

FIG. 6 is a demonstrative illustration of cross-sectional view of a device structure in a process of forming an electrode to a MRAM, following the step illustrated in FIG. 5, according to one embodiment of present invention. More specifically, embodiments of present invention provide performing a second etching of the modified layer 202, particularly the exposed portion of modified layer 202, to form connection layer 203 and at least one micro-stud 204. More particularly, a dielectric layer such as, for example, an organic planarization layer (OPL) may be deposited on top of the layer 301 of oxide or low-k dielectric material, covering exposed portion of the modified layer 202. Using a lithographic patterning process, a photo-resist pattern of the micro-stud 204 may be formed on a top surface of the modified layer 202. Subsequently, an etching process such as a reactive-ion-etching (RIE) process may be applied to etch and remove portions of the modified layer 202 that are not covered by the photo-resist pattern, to a depth corresponding to the thickness 230 of the micro-stud 204, resulting in the connection layer 203 with the thickness 220, and the micro-stud 204 of the thickness 230. As being illustrated in FIG. 6, the micro-stud 204 extends directly from the connection layer 203 which in-turn extends from the via 200 connecting to one of the source/drain contacts 101.

It is apparent from FIG. 6 that the micro-stud 204, the connection layer 203, and the via 200 are formed from a single uniform material of the layer 201. The layer 201 may be made of conductive material including, but not limited to, Ru, Co, Al, and W.

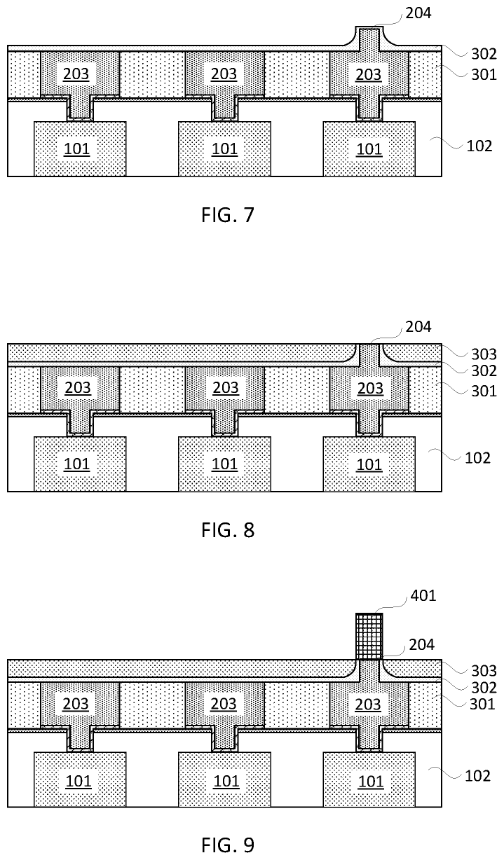

FIG. 7 is a demonstrative illustration of cross-sectional view of a device structure in a process of forming an electrode to a MRAM, following the step illustrated in FIG. 6, according to one embodiment of present invention. More specifically, embodiments of present invention provide forming a dielectric liner 302 covering micro-stud 204 at side as well as covering top of the layer 301 and connection layer 203. The dielectric liner 302 may be an NBLoK, SiC, SiCN, and/or SiN liner and may be a non-conformal liner. The dielectric liner 302 covers the micro-stud 204 and the connection layer 203, which may be Ru, Co, Al, or W such that the micro-stud 204 and the connection layer 203 may be isolated from getting direct contact with some low-k dielectric material layers such as a dielectric cap layer 303 (see FIG. 8), which would otherwise be contaminated.

FIG. 8 is demonstrative illustration of cross-sectional view of a device structure in a process of forming an electrode to a MRAM, following the step illustrated in FIG. 7, according to one embodiment of present invention. More specifically, a dielectric cap layer 303 may be formed on top of the dielectric liner 302 to a level above a top surface of the micro-stud 204. A CMP process may be subsequently used to planarize a top surface of the dielectric cap layer 303 and to expose the top surface of the micro-stud 204, preparing for the next step of forming a magnetic tunnel junction (MTJ) device on top of the micro-stud 204. The dielectric cap layer 303 may be a silicon oxide or any other suitable dielectric material, such as low-k dielectrics.

FIG. 9 is demonstrative illustration of cross-sectional view of a device structure in a process of forming an electrode to a MRAM, following the step illustrated in FIG. 8, according to one embodiment of present invention. More specifically, after the top surface of the micro-stud 204 is exposed, a MTJ device 401 is formed on top of and electrically connected at a first end thereof, i.e., a bottom thereof, to the micro-stud 204. The MTJ device 401 forms the core of the MRAM, is powered by the source/drain contact 101 of its access transistor through a conductive link having the via 200, the connection layer 203 and the micro-stud 204.

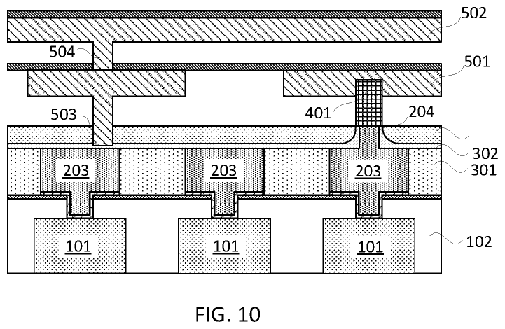

FIG. 10 is demonstrative illustration of cross-sectional view of a device structure in a process of forming an electrode to a MRAM, following the step illustrated in FIG. 9, according to one embodiment of present invention. More specifically, embodiments of present invention provide forming a bit line 501 in contact with the MTJ device 401 at a second end thereof, i.e., at a top portion of the MTJ device 401. Embodiments of present invention may further forming additional supporting circuitries such as a word line 502, as well as other metal lines and vias 503 and 504 in connection with the operation of the MRAM.

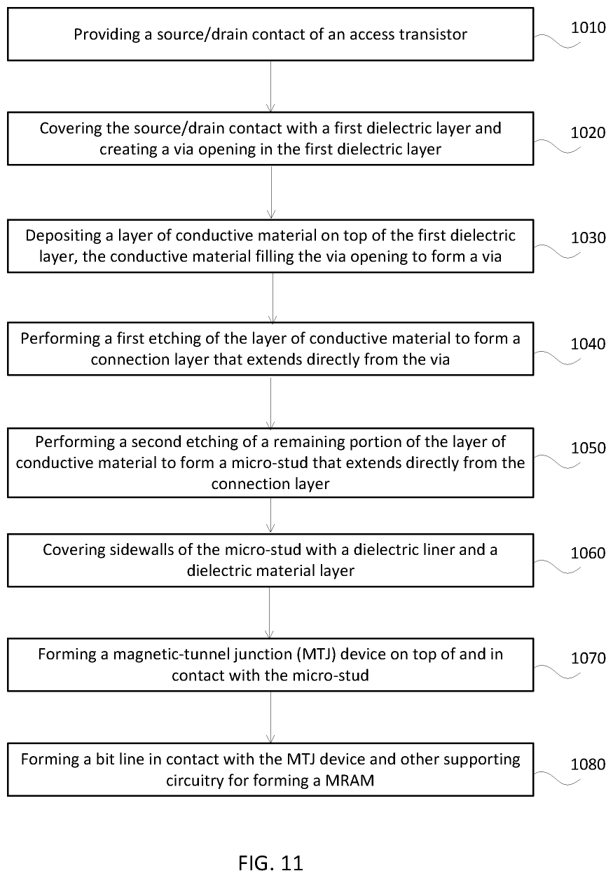

FIG. 11 is a demonstrative illustration of a flow-chart of a method of manufacturing an electrode to a MRAM according to embodiments of present invention. More specifically, the embodiment includes (1010) providing a source/drain contact of an access transistor; (1020) covering the source/drain contact with a first dielectric layer and subsequently creating a via opening in the first dielectric layer; (1030) depositing a layer of conductive material on top of the first dielectric layer, and the conductive material fills in the via opening to form a via; (1040) performing a first etching of the layer of conductive material to form a connection layer that extends directly from the via; (1050) performing a second etching of a remaining portion of the layer of conductive material to form a micro-stud that extends directly from the connection layer; (1060) covering the connection layer with a second dielectric layer, covering the micro-stud with a dielectric liner; covering the dielectric liner with a third dielectric layer and exposing a top surface of the micro-stud through a planarization; (1070) forming a magnetic-tunnel junction (MTJ) device on top of the micro-stud and in contact with the micro-stud; and (1080) forming a bit line in contact with the MTJ device and other supporting circuitry in forming the MRAM.

It is to be understood that the exemplary methods discussed herein may be readily incorporated with other semiconductor processing flows, semiconductor devices, and integrated circuits with various analog and digital circuitry or mixed-signal circuitry. In particular, integrated circuit dies can be fabricated with various devices such as field-effect transistors, bipolar transistors, metal-oxide-semiconductor transistors, diodes, capacitors, inductors, etc. An integrated circuit in accordance with the present invention can be employed in applications, hardware, and/or electronic systems. Suitable hardware and systems for implementing the invention may include, but are not limited to, personal computers, communication networks, electronic commerce systems, portable communications devices (e.g., cell phones), solid-state media storage devices, functional circuitry, etc. Systems and hardware incorporating such integrated circuits are considered part of the embodiments described herein. Given the teachings of the invention provided herein, one of ordinary skill in the art will be able to contemplate other implementations and applications of the techniques of the invention.

Accordingly, at least portions of one or more of the semiconductor structures described herein may be implemented in integrated circuits. The resulting integrated circuit chips may be distributed by the fabricator in raw wafer form (that is, as a single wafer that has multiple unpackaged chips), as a bare die, or in a packaged form. In the latter case the chip may be mounted in a single chip package (such as a plastic carrier, with leads that are affixed to a motherboard or other high-level carrier) or in a multichip package (such as a ceramic carrier that has surface interconnections and/or buried interconnections). In any case the chip may then be integrated with other chips, discrete circuit elements, and/or other signal processing devices as part of either an intermediate product, such as a motherboard, or an end product. The end product may be any product that includes integrated circuit chips, ranging from toys and other low-end applications to advanced computer products having a display, a keyboard or other input device, and a central processor.

The descriptions of various embodiments of present invention have been presented for the purposes of illustration and they are not intended to be exhaustive and present invention are not limited to the embodiments disclosed. The terminology used herein was chosen to best explain the principles of the embodiments, practical application or technical improvement over technologies found in the marketplace, and to enable others of ordinary skill in the art to understand the embodiments disclosed herein. Many modifications, substitutions, changes, and equivalents will now occur to those of ordinary skill in the art. Such changes, modification, and/or alternative embodiments may be made without departing from the spirit of present invention and are hereby all contemplated and considered within the scope of present invention. It is, therefore, to be understood that the appended claims are intended to cover all such modifications and changes as fall within the spirit of the invention.

What is claimed is:

1. A method comprising:
providing a supporting structure;
depositing a layer of conductive material on top of the supporting structure;
performing a first etching of the layer of conductive material to form a connection layer; and
performing a second etching of a remaining portion of the layer of conductive material to form a micro-stud, the micro-stud being directly above the connection layer.

2. The method of claim 1, wherein providing the supporting structure comprises:
providing a source/drain contact of an access transistor;
covering the source/drain contact with a first dielectric layer; and
creating a via opening in the first dielectric layer to form the supporting structure, with
the via opening exposing the source/drain contact of the access transistor.

3. The method of claim 2, wherein depositing the layer of conductive material comprises depositing the conductive material into the via open to form a via directly contacting the source/drain contact of the access transistor.

4. The method of claim 3, wherein the via, the connection layer, and the micro-stud together form a unitary unit of the conductive material.

5. The method of claim 1, further comprising:
covering the connection layer with a second dielectric layer;
covering the micro-stud with a dielectric liner;
covering the dielectric liner with a dielectric cap layer; and
planarizing the dielectric cap layer to expose a top surface of the micro-stud.

6. The method of claim 5, further comprising forming a magnetic-tunnel junction (MTJ) device on top of the micro-stud and forming a bit line in contact with the MTJ device.

7. The method of claim 5, wherein the dielectric liner is a non-conformal silicon-nitride layer.

8. The method of claim 1, wherein the conductive material is selected from a group consisting of ruthenium (Ru), cobalt (Co), aluminum (Al), and tungsten (W).

9. A method comprising:
providing a source/drain contact of an access transistor;
forming a first dielectric layer covering the source/drain contact;
creating a via opening in the first dielectric layer to expose the source/drain contact;
depositing a layer of conductive material over the first dielectric layer, the conductive material filling the via opening to form a via;
performing a first etching of the layer of conductive material to form a connection layer extended from the via;
performing a second etching of the layer of conductive material to form a micro-stud extended from the connection layer.

10. The method of claim 9, further comprising forming a magnetic-tunnel junction (MTJ) device having a first and a second contact area, the first contact area of the MTJ device being in contact with the micro-stud and forming a bit line in contact with the second contact area of the MTJ device.

11. The method of claim 10, further comprising forming a dielectric liner covering the micro-stud and the connection layer before forming the MTJ device.

12. The method of claim 11, wherein the dielectric liner is a non-conformal silicon-nitride (SiN) layer.

13. The method of claim 11, further comprising covering the connection layer in a second dielectric layer before forming the dielectric liner and subsequently covering the dielectric liner with a dielectric cap layer.

14. The method of claim 13, further comprising planarizing the dielectric cap layer to expose the micro-stud before forming the MTJ device.

15. The method of claim 9, wherein the layer of conductive material is a layer of ruthenium (Ru), a layer of cobalt (Co), a layer of aluminum (Al), or a layer of tungsten (W).

16. A magnetoresistive random-access memory (MRAM) structure comprising:
a magnetic-tunnel junction (MTJ) device having a first and a second contact areas;
a micro-stud in contact with the first contact area of the MTJ device; and
a bit line in contact with the second contact area of the MTJ device,
wherein the micro-stud is directly above a connection layer; the connection layer is directly above a via; and the via directly contacts a source/drain region of an access transistor, and wherein the micro-stud, the connection layer, and the via together form a single unit.

17. The MRAM structure of claim 16, wherein the micro-stud, the connection layer, and the via together are formed from a single uniform material, the single uniform material is selected from a group consisting of ruthenium (Ru), cobalt (Co), aluminum (Al), and tungsten (W).

18. The MRAM structure of claim 16, wherein the micro-stud is covered at side by a non-conformal dielectric layer.

19. The MRAM structure of claim 18, wherein the non-conformal dielectric layer is a silicon-nitride (SiN) layer.

20. The MRAM structure of claim 16, wherein the MTJ device is situated between two metal layers of a back-end-of-line (BEOL) structure.
